(19) United States
(12) Patent Application Publication
(10) Pub. No.: US 2010/0182586 A1
(43) Pub. Date: Jul. 22, 2010

(54) LITHOGRAPHY APPARATUS, AND METHOD OF MANUFACTURING DEVICE USING SAME

(75) Inventor: Takashi Ogura, Utsunomiya-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 12/689,002

(22) Filed: Jan. 18, 2010

(30) Foreign Application Priority Data
Jan. 19, 2009 (JP) 2009-009050

(51) Int. Cl. G03B 27/32; H01L 21/677; H01L 21/673

(52) U.S. Cl. 355/77; 414/222.01

(57) ABSTRACT

The Lithography apparatus of the present invention includes a container conveyance unit configured to convey a sealed container accommodating a substrate from the exterior of the apparatus to the interior of the apparatus, an opener provided in the interior of the lithography apparatus for opening and closing a front door of the sealed container, and a substrate conveyance unit configured to convey the substrate accommodated in the sealed container to a processing section. The container conveyance unit is extendable and retractable so as to be accommodated in the interior of the apparatus when the sealed container is conveyed from the exterior of the apparatus to the interior of the apparatus.

### BACKGROUND OF THE INVENTION

1. Field of the Invention

The present invention relates to a Lithography apparatus and a method of manufacturing a device using the same.

2. Description of the Related Art

In recent years, as a means for attaining cost reductions in semiconductor manufacturing processes, the level of cleanliness of clean rooms has been lowered. A substrate (wafer) conveyance under this environment is carried out by accommodating a wafer in a sealed container for maintaining the cleanliness and carrying the container into the interior of the semiconductor manufacturing apparatus without exposing the wafer to air in the clean room. With increasing sizes of semiconductor wafers, the sealed container often used is a FOUP (Front Opening Unified Pod) container having a front door.

Japanese Patent Laid-Open No. 2001-274220 discloses a semiconductor manufacturing apparatus that prevents changes in atmospheric pressure in the interior of the apparatus, an increase in oxygen concentration, deterioration of intensity of exposure light, and the like by measuring and adjusting the state of the gas in the FOUP when the door of the FOUP is in close contact with the opening of the FOUP opener. In addition, Japanese Patent Laid-Open No. 2004-349380 discloses a conveyance apparatus for conveying a semiconductor device that installs a FOUP opener having only a dock table driving mechanism in the interior of the apparatus so that the proportion of the footprint of a stocker in a semiconductor manufacturing line can be reduced.

However, the FOUP disclosed in Japanese Patent Laid-Open No. 2001-274220 is not included in the standard configuration but is often used as an option. For this reason, the FOUP opener is installed at the exterior of the semiconductor device and is often used with it secured in close contact with the side of the device. Therefore, the device arrangement using the FOUP requires space at the exterior of the device, resulting in an increase in the footprint of the overall device. In this case, when a wafer is carried in or out of the inside of the FOUP, the conveyance distance of the wafer becomes longer, resulting in the extension of conveyance time. Furthermore, a wafer transfer mechanism is generally not provided between the FOUP and the device, and hence a relay unit with a mechanism having a transfer function must be provided.

The conveyance apparatus for conveying a semiconductor device disclosed in Japanese Patent Laid-Open No. 2004-349380 reduces the footprint of the apparatus. However, in order to place the FOUP in the apparatus, space is required on the upper part of the FOUP, because the FOUP is carried into the FOUP's mounting platform included in the apparatus in its floating state from the mounting platform. If the apparatus is compatible for use with a wafer OHT (Overhead Hoist Transport) or the like, the entire upper part of the FOUP must be hollowed out. In other words, additional space is required in the interior of the semiconductor device itself.

### SUMMARY OF THE INVENTION

The present invention provides a lithography apparatus which uses a FOUP and does not cause an increase in the footprint or the space in the interior of the apparatus itself.

According to an aspect of the present invention, a lithography apparatus for exposing a substrate is provided that includes a container conveyance unit configured to convey a sealed container that accommodates a substrate from the exterior of the apparatus to the interior of the apparatus; an opener provided in the interior of the apparatus and for opening and closing the front door of the sealed container; and a substrate conveyance unit configured to convey the substrate accommodated in the sealed container to a processing section, wherein the container conveyance unit is extendable and retractable so as to be accommodated in the interior of the apparatus when the sealed container is conveyed from the exterior of the apparatus to the interior of the apparatus.

Further features of the present invention will become apparent from the following description of exemplary embodiments with reference to the attached drawings.

### BRIEF DESCRIPTION OF THE DRAWINGS

FIG. 1 is a schematic view showing the body portion of an exposure apparatus according to an embodiment of the present invention.

FIG. 2 is a schematic view showing a device manufacturing apparatus according to an embodiment of the present invention.

FIG. 3 is a schematic view showing a portion of the conveyance unit in the conventional exposure apparatus.

FIG. 4 is a schematic view showing a portion of the conveyance unit in the exposure apparatus of the present invention.

FIG. 5 is a schematic view showing the operation of the FOUP opener according to the exposure apparatus of the present invention.

FIG. 6 is a schematic view showing the operation of the FOUP opener according to the exposure apparatus of the present invention.

FIG. 7 is a schematic view showing the operation of the FOUP opener according to the exposure apparatus of the present invention.

FIG. 8 is a schematic view showing the operation of the FOUP opener according to the exposure apparatus of the present invention.

FIG. 9 is a schematic view showing the operation of the FOUP opener according to the exposure apparatus of the present invention.

FIG. 10 is a schematic view showing the operation of the FOUP opener according to the exposure apparatus of the present invention.

FIG. 11 is a schematic view showing the operation of the FOUP opener according to the exposure apparatus of the present invention.

FIG. 12 is a schematic view showing the operation of the FOUP opener according to the exposure apparatus of the present invention.

FIG. 13 is a schematic view showing the operation of the FOUP opener according to the exposure apparatus of the present invention.

### DESCRIPTION OF THE EMBODIMENTS

Hereinafter, the embodiments of the present invention will now be described with reference to the accompanying drawings.

FIG. 1 is a schematic view showing the body portion (hereinafter referred to as “exposure unit”) of an exposure apparatus according to an embodiment of the present invention. An exposure unit 1 is an apparatus that exposes a reticle pattern onto a wafer by a step-and-scan method or a step-and-repeat method, but the exposure method is not particularly limited. For the purpose of explanation, in FIG. 1, the Z axis is aligned parallel to the optical axis of the projection optical system constituting the exposure unit 1, the Y axis is aligned in the scanning direction of a reticle (original) and a wafer (substrate) during scanning exposure in the plane perpendicular to the Z axis, and the X axis is aligned in the non-scanning direction perpendicular to the Y axis. The exposure unit 1 includes an illumination optical system 2, a reticle stage 4 that holds a reticle 3 in which a pattern has been formed, a reticle position measurement unit 5, a projection optical system 6, and a stage device 8 that positions a wafer 7 to which a photoresist is applied.

The illumination optical system 2 introduces illumination light through a beam line from a built-in light source (not shown) (electric-discharge lamp such as extra high pressure mercury lamp) or a light source device provided separately from the exposure unit 1, and generates slit light by various lenses and stops to illuminate the reticle 3 from above. The reticle stage 4 is a stage that is movable in the X and Y directions. The reticle position measurement unit 5 is a device that measures the position of the reticle 3. The projection optical system 6 contracts and projects the pattern of the reticle 3 onto the wafer 7 at a predetermined magnification (e.g., 4:1). In addition, the stage device 8 includes a XY stage 9 that can move the wafer 7 in the X and Y directions, and a Z stage 10 that can move the wafer 7 in the Z direction. Furthermore, the exposure unit 1 includes a laser interferometer 11 that measures the position of the XY stage 9 in the X and Y directions, and a focus unit 12 that measures the position of the wafer 7 in the Z direction.

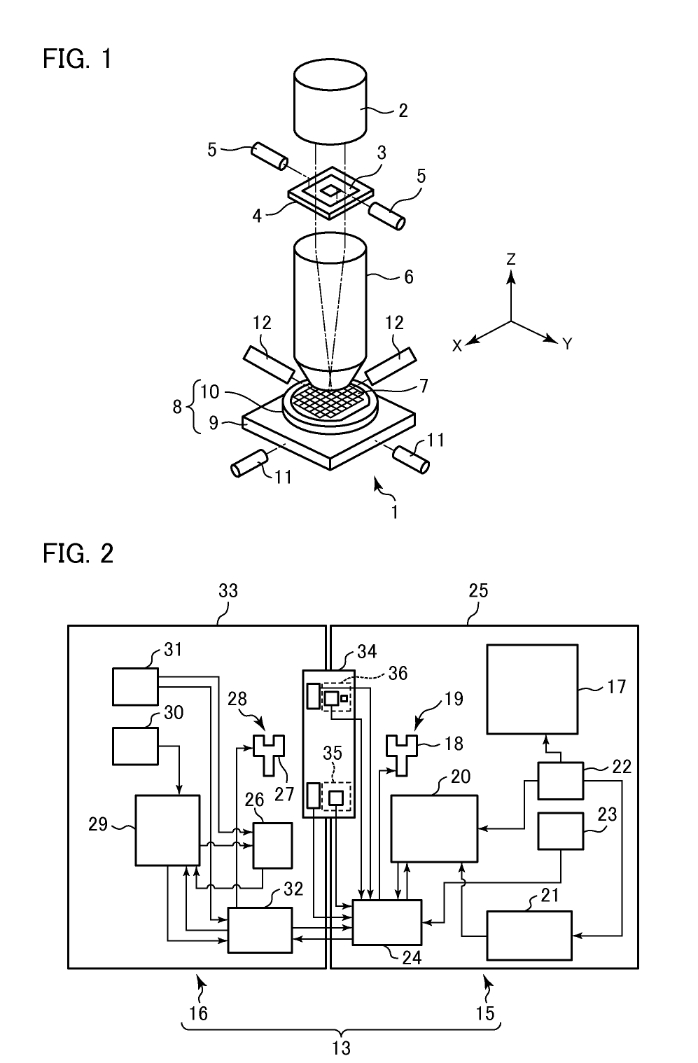

FIG. 2 is a schematic view (plan view) showing a device manufacturing apparatus according to an embodiment of the present invention. A device manufacturing apparatus 13 consists of an exposure apparatus 15 having the exposure unit 1 shown in FIG. 1, and a coating/developing apparatus 16.

The exposure apparatus 15 includes an exposure processing section 17 including the exposure unit 1, a first conveyance unit 19 including a hand 18 that holds a wafer, i.e., an object to be treated, a control section 20 that controls the exposure apparatus 15, and an input/output device 21 which is an user interface. Furthermore, the exposure apparatus 15 includes a main power supply 22, an auxiliary power supply 23, and a first conveyance control section 24 that controls the first conveyance unit 19. Each of these components is disposed within an exposure chamber 25.

Here, the main power supply 22 provides power at least to the exposure processing section 17, the control section 20, and the input/output device 21. In contrast, the auxiliary power supply 23 provides power to the first conveyance control section 24. The auxiliary power supply 23 is configured to replace the main power supply 22 to continue the power supply when the power supply to an object that is supplied with power by the main power supply 22 is interrupted. More specifically, the auxiliary power supply 23 is arranged to include, for example, a secondary battery. In this case, the auxiliary power supply 23 charges the secondary battery by electrical power provided from the main power supply 22 when the main power supply 22 is normal. On the other hand, the object to which power is supplied is powered by the secondary battery when the power supply provided by the main power supply 22 is interrupted by the abnormalities or power failure of the main power supply 22.

The coating/developing apparatus 16 includes an coating/development section 26 including an coating/development unit that serves to apply a photoresist onto a wafer and to develop the exposed wafer, a second conveyance unit 28 including a hand 27 that holds a wafer, and a control section 29 that controls the coating/developing apparatus 16. Furthermore, the coating/developing apparatus 16 includes a main power supply 30, an auxiliary power supply 31, and a second conveyance control section 32 that controls the second conveyance unit 28. Each of these components is disposed within an coating/development chamber 33. Note that the operations of the main power supply 30 and the auxiliary power supply 31 are the same as those of the main power supply 22 and the auxiliary power supply 23 that are provided in the exposure apparatus 15 described above.

In addition, the device manufacturing apparatus 13 includes a transfer station 34 that transfers a wafer between the exposure apparatus 15 and the coating/developing apparatus 16. First, the second conveyance unit 28 conveys a photoresist-coated wafer to a carrying-in section 35 in the transfer station 34. The first conveyance unit 19 receives the wafer that has been conveyed in the carrying-in section 35 and conveys the wafer to the exposure processing section 17. After the completion of exposure processing, the first conveyance unit 19 conveys the wafer from the exposure processing section 17 to a carrying-out section 36 in the transfer station 34. The second conveyance unit 28 then receives the wafer that has been conveyed in the carrying-out section 36 and conveys the wafer to the coating/development section 26 for development processing.

Note that the first conveyance unit 19 may convey a wafer to the XY stage 9 shown in FIG. 1 via a wafer alignment unit (not shown). Furthermore, the exposure apparatus 15 may include a plurality of wafer conveyance units.

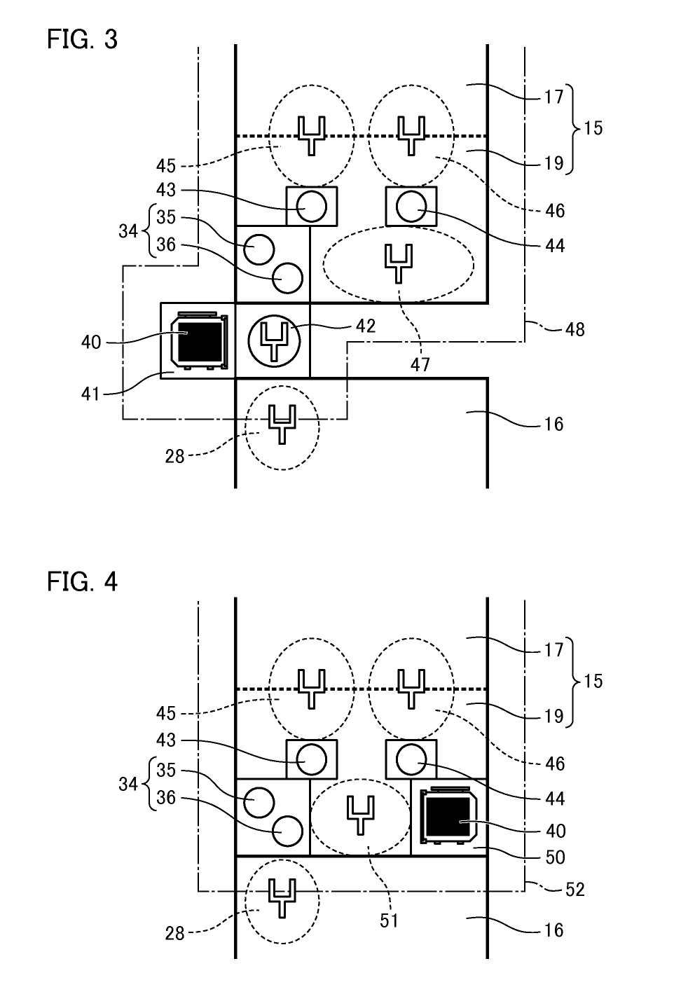

Next, the conveyance unit, which is a feature of the exposure apparatus of the present invention, will be described in comparison with the conventional exposure apparatus. In FIG. 3, the same elements as those shown in FIG. 2 are designated by the same reference numerals and explanation thereof will be omitted. FIG. 3 is a schematic view showing a portion of the conventional conveyance unit in the device manufacturing apparatus shown in FIG. 2. The device manufacturing apparatus shown in FIG. 3 consists of the area of the exposure apparatus 15 (shown as a thick line in the upper part of FIG. 3) and the area of the coating/developing apparatus 16 (shown as a thick line in the lower part of FIG. 3). A sealed container FOUP 40 is used as an option of the device. The exposure apparatus 15 consists of the area in which the exposure processing section 17 is disposed, and the area in which the first conveyance unit 19 is disposed. Furthermore, the device manufacturing apparatus includes a FOUP opener 41 and a relay unit 42. In the standard configuration of the conventional exposure apparatus, the FOUP opener 41 and the relay unit 42 are absent. Since there is no space for the placement of these components in the interior of the exposure apparatus 15, they are disposed at the exterior of the exposure apparatus 15 as shown in FIG. 3.

The first conveyance unit 19 includes the transfer station 34 including the carrying-in section 35 and the carrying-out section 36 that transfer a wafer with the coating/developing apparatus 16, a carrying-in station 43, and a carrying-out station 44. Furthermore, each carrying-in station 43 and the carrying-out station 44 includes a carrying-in unit 45, a carrying-out unit 46, and a conveyance unit 47 that transfer a wafer with the exposure processing section 17.

Here, the conveyance configuration of a wafer within the conveyance unit is broadly classified into two types. The first conveyance configuration is to carry in/out a wafer from the coating/developing apparatus 16 (hereinafter referred to as “in-line conveyance”). The second conveyance configuration is to carry in/out a wafer from a carrier such as the FOUP 40 (hereinafter referred to as “carrier conveyance”). The device manufacturing apparatus shown in FIG. 3 is compatible with either of these two conveyance configurations. Each of the conveyance configurations will be described hereinbelow.

First, the wafer conveyance method in the case that the in-line conveyance is employed will be described. The second conveyance unit 28 in the coating/developing apparatus 16 transfers a wafer to the relay unit 42. Subsequently, the relay unit 42 conveys the wafer to the carrying-in section 35. Next, the conveyance unit 47 conveys the wafer from the carrying-in section 35 to the carrying-in station 43. Subsequently, the carrying-in unit 45 conveys the wafer from the carrying-in station 43 to the exposure processing section 17. Next, the carrying-out unit 46 conveys the wafer 7 subjected to exposure processing at the exposure processing section 17 to the carrying-out station 44. Next, the conveyance unit 47 conveys the wafer to the carrying-out section 36. Subsequently, the relay unit 42 and the second conveyance unit 28 convey the wafer to the coating/developing apparatus 16.

In the above description regarding the in-line conveyance, the conveyance configuration of the wafer conveyance method in the case that the carrier conveyance is employed is such that the coating/developing apparatus 16 and the second conveyance unit 28 are replaced with the FOUP 40 and the FOUP opener 41, respectively.

In the conventional conveyance unit described above, the FOUP opener 41 and the relay unit 42 must be provided in order to carry out carrier conveyance using the FOUP 40. Hence, the installation area (footprint) 48 of the exposure apparatus 15 is the area drawn with a dot-dash line in FIG. 3.

FIG. 4 is a schematic view showing a portion of the conveyance unit of the present invention in comparison with the conventional conveyance unit shown in FIG. 3. In FIG. 4, the same elements as those shown in FIG. 3 are designated by the same reference numerals and explanation thereof will be omitted. A feature of the present invention is to place a FOUP opener 50 in the interior of the exposure apparatus 15. Furthermore, instead of the conveyance unit 47 in the exposure apparatus 15, a space-saving conveyance unit (substrate conveyance unit) 51, which can provide the same level of transferring as the conventional conveyance unit, is employed.

The conveyance unit 51 conveys a wafer from the conventional transfer station 34 to the exposure processing section 17, and conveys a wafer from the FOUP 40 to the exposure processing section 17 as well. With this arrangement, the relay unit 42 which is required in the conventional device manufacturing apparatus becomes unnecessary. Thus, the conveyance distance in the carrier conveyance is shortened and the conveyance time thereby becomes shorter, which leads to an improvement in throughput. Furthermore, the footprint 52 of the exposure apparatus 15 is the area drawn with a dot-dash line in FIG. 4, and the area is contracted compared with the footprint 48 shown in FIG. 3. Similarly, even when the in-line conveyance is employed, the exposure apparatus 15 and the coating/developing apparatus 16 can be disposed in close contact with each other. Consequently, the conveyance distance of a wafer is shortened and the conveyance time thereby becomes shorter, which leads to an improvement in throughput.

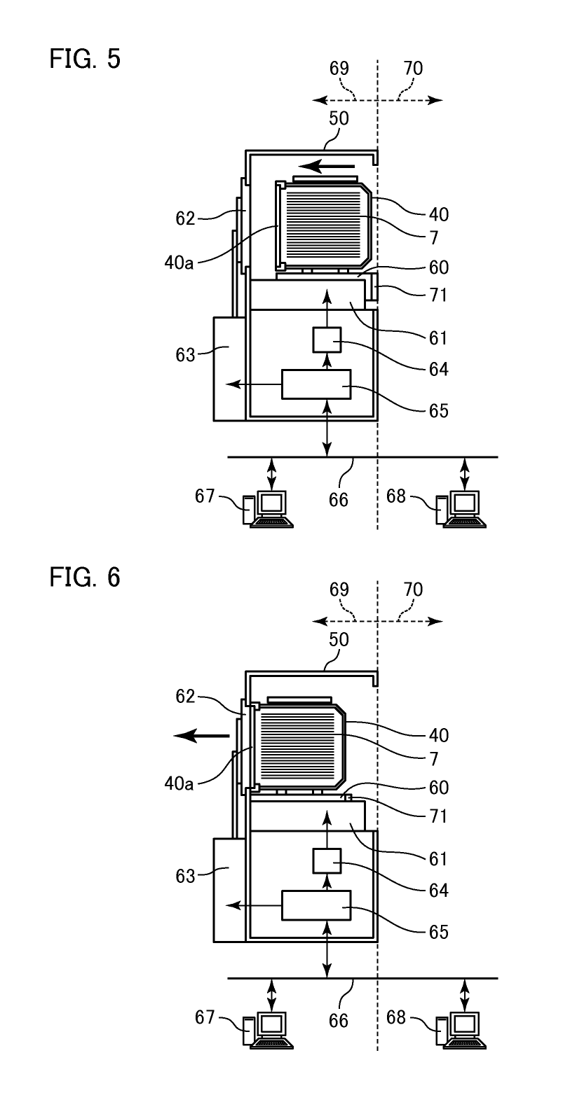

Next, the FOUP opener 50 shown in FIG. 4 will be described with reference to FIGS. 5 to 13. Each of FIGS. 5 to 13 is a schematic view (side view) showing the sequence of operations of the FOUP opener 50 having a horizontal driving mechanism as a feature of the present invention.

First, the configuration of the FOUP opener 50 will be described. The FOUP opener 50 includes a horizontal driving mechanism consisting of a first drive table (hereinafter referred to as “dock table”) 60 and a second drive table (hereinafter referred to as “slide table”) 61 that are extendable and retractable in the horizontal direction while placing the FOUP 40 thereon. The horizontal driving mechanism is a container conveyance unit that conveys the FOUP 40 housing a wafer from the exterior of the exposure apparatus 15 to the interior of the exposure apparatus 15. A dock table 60 places the FOUP 40 thereon, and is movable in the horizontal direction on a slide table 61. The slide table 61 is movable in the horizontal direction while movably supporting the dock table 60. The FOUP opener 50 includes a door opener (opener) 62 that opens and closes the front door 40a of the FOUP 40 to hold them, and a door opener driving mechanism section 63 that drives the door opener 62.

Furthermore, the FOUP opener 50 includes a horizontal mechanism drive section 64 that drives the dock table 60 and the slide table 61, and a drive control section 65 that controls the door opener driving mechanism section 63 and the horizontal mechanism drive section 64. The drive control section 65 is connected to a FOUP opener control section 67 in the interior of the exposure apparatus and a FOUP opener control section 68 at the exterior of the exposure apparatus via the network 66. For example, for the FOUP opener control section 67, a device that emits a control signal from the interior of the exposure apparatus is employed such as the input/output device 21 (e.g., operation panel) as a user interface, a push switch, an upper control section in the exposure apparatus, or the like. On the other hand, for the FOUP opener control section 68, a device that emits a control signal from the exterior of the exposure apparatus is employed such as any other device other than the exposure apparatus, a FOUP automatic loading/unloading device (e.g., wafer OHT), or the like. The left side represents the interior of the exposure apparatus 69 and the right side represents the exterior of the exposure apparatus 70, where a dotted line in the Figure corresponds to the boundary therebetween.

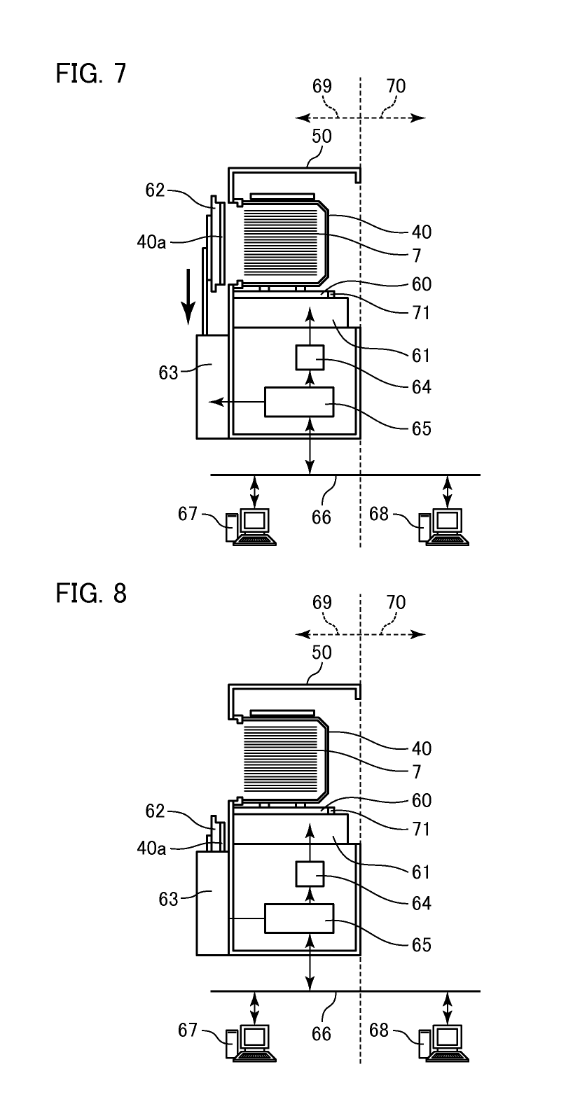

Next, operation of the FOUP opener 50 will be described. First, with reference to FIGS. 5 to 8, a description will be given in the case where the door open command is given from the FOUP opener control sections 67 and 68 that are provided in the interior and at the exterior of the exposure apparatus, respectively. FIG. 5 is a view showing the state in which the FOUP 40 is placed on the dock table 60 and the FOUP 40 is accommodated in the FOUP opener 50. At this time, the FOUP 40 is in a sealed state with the front door 40a closed. First, in FIG. 5, the drive control section 65 provides a drive command to the horizontal mechanism drive section 64 to move the dock table 60 at the position shown in FIG. 6. Next, in FIG. 6, the door opener 62 unlocks the front door 40a and performs an operation such as absorption to hold the front door 40a. Subsequently, the drive control section 65 provides a drive command to the door opener driving mechanism section 63 to move the door opener 62 which holds the front door 40a at the position shown in FIG. 7. In FIG. 7, the drive control section 65 provides a drive command to the door opener driving mechanism section 63 to move the door opener 62 at the position shown in FIG. 8. When the door close command is given from the FOUP opener control sections 67 and 68 that are provided in the interior and at the exterior of the exposure apparatus, respectively, the aforementioned procedure for driving the door to open is reversed.

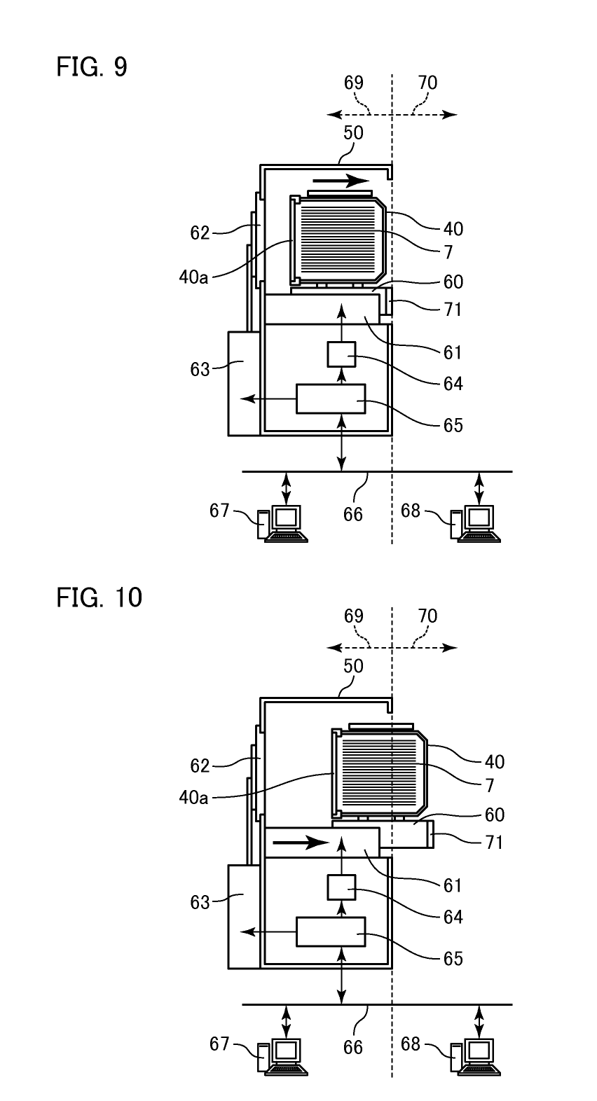

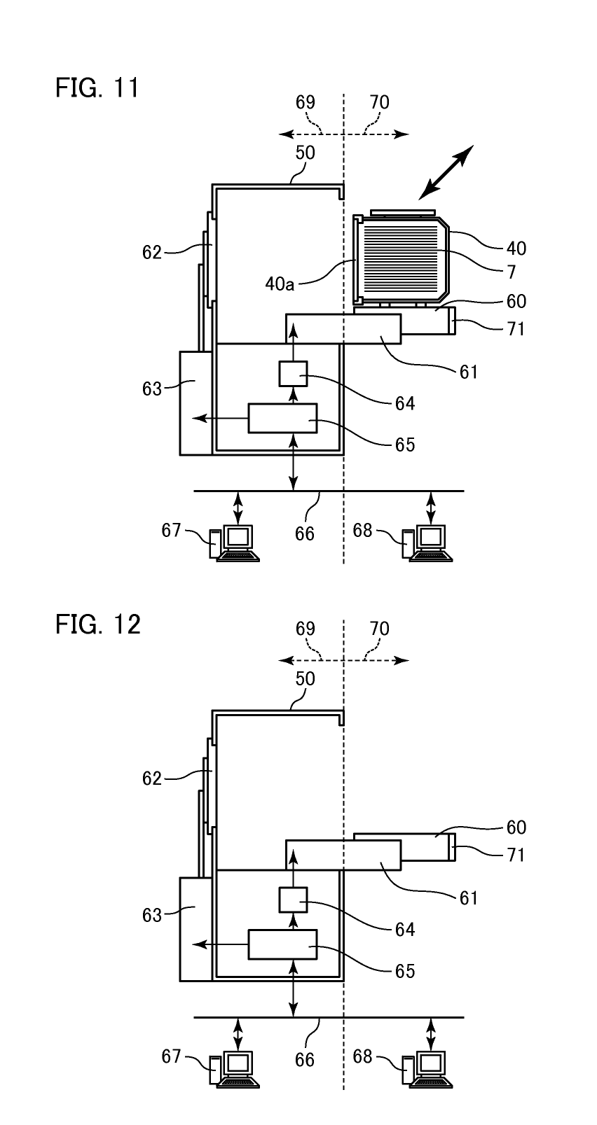

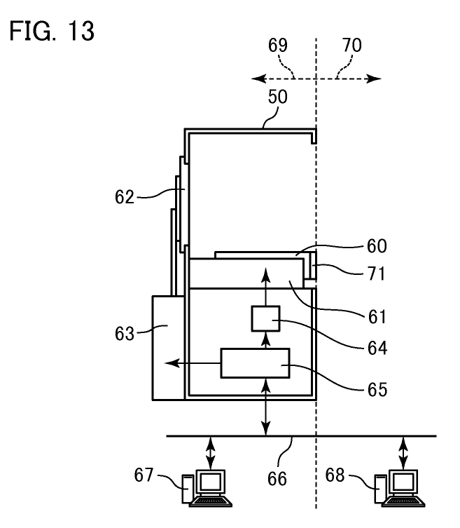

Next, with reference to FIGS. 9 to 11, a description will be given in the case where the loading/unloading command of the FOUP 40 is given from the FOUP opener control sections 67 and 68 that are provided in the interior and at the exterior of the exposure apparatus, respectively. FIG. 9 is a view showing the state in which the FOUP 40 is placed on the dock table 60. First, in FIG. 9, the drive control section 65 provides a drive command to the horizontal mechanism drive section 64 to move the dock table 60 at the position shown in FIG. 10. Next, in FIG. 10, the drive control section 65 provides a drive command to the horizontal mechanism drive section 64 to move the slide table 61 at the position shown in FIG. 11. The dock table 60 includes an interlock mechanism 71 such as a contact switch to allow the driving of the dock table 60 to stop for security purposes when an obstacle such as an operator or object is present within a driving range of the dock table 60 and the slide table 61. In FIG. 11, an operator or a FOUP transfer robot (not shown) performs the loading/unloading of the FOUP 40. In this manner, the loading/unloading drive of the FOUP 40 can be performed while maintaining a positive pressure within the exposure apparatus. Note that the dock table 60 on which the FOUP 40 is placed and the slide table 61 are returned to the position shown in FIG. 9 by reversing the driving procedure shown in FIGS. 9 to 11. Finally, as shown in FIGS. 12 and 13, when the FOUP opener 50 does not carry the FOUP 40, the dock table 60 and the slide table 61 can be moved from the position shown in FIG. 12 to the position shown in FIG. 13 by reversing the driving procedure shown in FIGS. 9 to 11. Similarly, the dock table 60 and the slide table 61 can be moved from the position shown in FIG. 13 to the position shown in FIG. 12 by performing the same driving procedure as that shown in FIGS. 9 to 11.

Although the driving of the dock table 60 and the slide table 61 is limited only to the horizontal driving in the foregoing embodiment, they may be used in combination with a spiral driving mechanism that can appropriately change the horizontal orientation of the FOUP 40.

As described above, according to the exposure apparatus of the present invention, even when the FOUP is used, the footprint of the entire exposure apparatus is equivalent to the case where the conventional FOUP is not used, in other words, the footprint can be minimized. In addition, since the FOUP is installed in the interior of the exposure apparatus, the conveyance distance is shortened and the conveyance time thereby becomes shorter, which leads to an improvement in throughput compared with the conventional exposure apparatus in which the FOUP is installed at the exterior thereof.

In addition, the horizontal driving mechanism is extendable and retractable so as to be accommodated in the interior of the exposure apparatus, whereby the space inside the exposure apparatus can be minimized. With this arrangement, there is no need to provide any special area for a wafer OHT within the exposure apparatus. Similarly, the loading/unloading operation of the FOUP can be performed without using any special tool. Note that the horizontal driving mechanism overhangs outside the exposure apparatus upon placing the FOUP, but falls within the maintenance area around the normal exposure apparatus.

### (Device Manufacturing Method)

Next, a method of manufacturing a device (semiconductor device, liquid crystal display device, etc.) as an embodiment of the present invention is described.

The semiconductor device is manufactured through a front-end process in which an integrated circuit is formed on a wafer, and a back-end process in which an integrated circuit chip is completed as a product from the integrated circuit on the wafer formed in the front-end process. The front-end process includes a step of exposing a wafer coated with a photoresist to light using the above-described exposure apparatus of the present invention, and a step of developing the exposed wafer. The back-end process includes an assembly step (dicing and bonding), and a packaging step (sealing). The liquid crystal display device is manufactured through a process in which a transparent electrode is formed. The process of forming a plurality of transparent electrodes includes a step of coating a glass substrate with a transparent conductive film deposited thereon with a photoresist, a step of exposing the glass substrate coated with the photoresist thereon to light using the above-described exposure apparatus, and a step of developing the exposed glass substrate. The device manufacturing method of this embodiment has an advantage, as compared with a conventional device manufacturing method, in at least one of performance, quality, productivity and production cost of a device.

While the embodiments of the present invention have been described with reference to exemplary embodiments, it is to be understood that the invention is not limited to the disclosed exemplary embodiments. The scope of the following claims is to be accorded the broadest interpretation so as to encompass all such modifications and equivalent structures and functions. The present invention is accommodated to another lithography apparatus, including imprint lithography apparatus, or charged particle beam lithography apparatus. So, terms “radiation” and “beam” used herein involve all types of electromagnetic radiation, including ultraviolet radiation and extreme ultra-violet radiation, as well as charged particle beams, such as ion beams or electron beams.

This application claims the benefit of Japanese Patent Application No. 2009-009050 filed Jan. 19, 2009 which is hereby incorporated by reference herein in its entirety.

What is claimed is:

1. A lithography apparatus for forming a pattern on a substrate, comprising:
a container conveyance unit configured to convey a sealed container accommodating the substrate from an exterior of the apparatus to an interior of the apparatus;
an opener provided in the interior of the apparatus for opening and closing a front door of the sealed container; and
a substrate conveyance unit configured to convey the substrate in the sealed container to a processing section,
wherein the container conveyance unit is extendable and retractable so as to be accommodated in the interior of the apparatus when the sealed container is conveyed from the exterior of the apparatus to the interior of the apparatus.

2. The lithography apparatus according to claim 1, wherein the container conveyance unit is a horizontal driving mechanism comprising a first drive table on which the sealed container is mountable, and a second drive table that movably supports the first drive table.

3. The lithography apparatus according to claim 1, wherein the container conveyance unit comprises a spiral driving mechanism that can change the orientation of the sealed container in a horizontal direction.

4. The lithography apparatus according to claim 1, wherein the container conveyance unit comprises an interlock mechanism that can stop driving when an obstacle is present within a driving range.

5. The lithography apparatus according to claim 1, wherein the apparatus comprises a transfer station configured to transfer the substrate between devices other than the apparatus in the interior of the apparatus, and the substrate conveyance unit conveys the substrate between the processing section and the transfer station.

6. A method of manufacturing a device, comprising:
radiating a beam from a beam source onto a substrate using a lithography apparatus for forming a pattern on the substrate, wherein the lithography apparatus comprises:
a container conveyance unit configured to convey a sealed container accommodating the substrate from an exterior of the apparatus to an interior of the apparatus;
an opener provided in the interior of the apparatus for opening and closing a front door of the sealed container; and
a substrate conveyance unit configured to convey the substrate in the sealed container to a processing section,
wherein the container conveyance unit is extendable and retractable so as to be accommodated in the interior of the apparatus when the sealed container is conveyed from the exterior of the apparatus to the interior of the apparatus, and
developing the substrate.
